(19) United States
(12) Patent Application Publication
(10) Pub. No.: US 2001/0038699 A1
(43) Pub. Date: Nov. 8, 2001

(54) Automatic directional processing control for multi-microphone system

(75) Inventor: Zezhang Hou, Cupertino, CA (US)

Correspondence Address: BEYER WEAVER & THOMAS LLP, P.O. BOX 778, BERKELEY, CA, 94704-0778, US

(73) Assignee: Audia Technology, Inc.

(21) Appl. No.: 09/813,430

(22) Filed: Mar. 20, 2001

Related U.S. Application Data
(60) Provisional application No. 60/190,579, filed on Mar. 20, 2000.

(51) Int. Cl. H04R 3/00; H03G 3/20

(52) U.S. Cl. 381/92; 381/57; 381/91; 381/122

(57) ABSTRACT

Improved approaches to control directional processing in multi-microphone processing systems. These approaches operate to control activation/deactivation of directional processing in multi-microphone processing systems. As a result, directional processing can be automatically activated or deactivated based on the amount of interference (e.g., noise) in the listening environment. These approaches are particularly useful for hearing aid applications in which directional noise suppression is important.

### CROSS-REFERENCE TO RELATED APPLICATIONS

This application claims the benefit of U.S. Provisional Application No. 60/190,579, filed Mar. 20, 2000, and entitled “AUTOMATIC DIRECTIONAL PROCESSING IN MULTI-MICROPHONE SYSTEM”, the contents of which is hereby incorporated by reference. This application is also related to (i) U.S. application Ser. No. 09/788,271, filed Feb. 16, 2001, and entitled “NULL ADAPTATION IN MULTI-MICROPHONE DIRECTIONAL SYSTEM”, the contents of which is hereby incorporated by reference; and (ii) U.S. application Ser. No. 09/______, filed Mar. 14, 2001, and entitled “ADAPTIVE MICROPHONE MATCHING IN MULTI-MICROPHONE DIRECTIONAL SYSTEM”, the contents of which is hereby incorporated by reference.

### BACKGROUND OF THE INVENTION

1. Field of the Invention

The present invention relates to multi-microphone sound pick-up systems and, more particularly, to directional processing in multi-microphone sound pick-up systems.

2. Description of the Related Art

Suppressing interfering noise is still a major challenge for most communication devices involving a sound pick up system such as a microphone or a multi-microphone array. The multi-microphone array can selectively enhance sounds coming from certain directions while suppressing interference coming from other directions.

FIG.1 shows a typical directional processing system in a two-microphone hearing aid. The two microphones pick-up sounds and convert them into electronic or digital signals. The output signal from the second microphone is delayed and subtracted from the output signal of the first microphone. The result is a signal with interference from certain directions being suppressed. In other words, the output signal is dependent on which directions the input signals come from. Therefore, the system is directional. The physical distance between the two microphones and the delay are two variables that control the characteristics of the directionality. For hearing aid applications, the physical distance is limited by the physical dimension of the hearing aid. The delay can be set in a delta-sigma analog-to-digital converter (A/D) or by use of an all-pass filter.

Although the typical directional processing system, such as shown in FIG. 1, is able to suppress interference from certain directions, the typical directional processing also has some disadvantages. One disadvantage is that the frequency response of the typical directional processing system is like a high-pass filter, with low frequency components attenuated more than high frequency components. This is so-called a low frequency roll-off phenomenon. Another disadvantage is that the noise floor of the typical directional processing system is higher than with a single microphone. This is because each microphone has a noise floor. The typical directional processing system has more than one microphone and the combined noise floor of two microphones is always higher than that of a single microphone. Accordingly, it is desirable to turn-off the directional processing during quiet periods to avoid these two disadvantages.

Most existing hearing aids that perform directional processing provide a manual means for users to turn the directional processing on or off. Recently, U.S. Pat. No. 5,214,709 proposed a method to turn the directional processing on/off simply based on the level of the microphone response. One problem with such a design is that the turning of the directional processing on/off is not based on whether the environment is noisy or quiet. As a result, high-level clean speech could trigger the directional processing even though unwanted. Further, because the triggering of directional processing is simply based on a voltage level of the microphone response, the fluctuation in speech signal could undesirably turn the directional processing on and off, which is very annoying for users.

Thus, there is a need for improved approaches to control directional processing in multi-microphone processing systems.

### SUMMARY OF THE INVENTION

Broadly speaking, the invention relates to improved approaches to control directional processing in multi-microphone processing systems. These approaches operate to control activation/deactivation of directional processing in multi-microphone processing systems. As a result, directional processing can be automatically activated or deactivated based on the amount of interference (e.g., noise) in a listening environment. These approaches are particularly useful for hearing aid applications in which directional noise suppression is important.

The invention can be implemented in numerous ways including as a method, system, apparatus, device, and computer readable medium. Several embodiments of the invention are discussed below.

As a directional sound processing system, one embodiment of the invention includes at least: at least first and second microphones spaced apart by a distance, the first microphone producing a first electronic sound signal and the second microphone producing a second electronic sound signal; a noise level estimate circuit operatively coupled to the first or second microphone, the noise level estimate circuit operates to produce a noise level estimate associated with the first or second electronic sound signal from the first or second microphone; and a directional processing circuit operatively connected to the first and second microphones and the noise level estimate circuit, the directional processing circuit operates to activated or deactivate directional processing with respect to the first and second electronic sound signals based on the noise level estimate.

As a directional sound processing system, another embodiment of the invention includes at least: at least first and second microphones spaced apart by a distance, the first microphone producing a first electronic sound signal and the second microphone producing a second electronic sound signal; a minimum estimate circuit operatively coupled to the first or second microphone, the minimum estimate circuit produces a minimum estimate for the first or second electronic sound signal from the first or second microphone; a directional processing control circuit operatively coupled to the minimum estimate circuit, the directional processing control circuit produces a control signal based on the minimum estimate; and a scaling circuit operatively connected to the directional processing control circuit, the scaling circuit operates to scale the second electronic sound signal in accordance with the control signal; and a subtraction circuit operatively connected to the scaling circuit and the first microphone, the subtraction circuit producing an output difference signal by subtracting the scaled second electronic sound signal from the first electronic sound signal.

As a hearing aid device having a multi-microphone sound processing device that performs a method for dynamically controlling directional processing in the multi-microphone sound processing system, one embodiment of the invention includes at least the acts of: receiving first and second electronic sound signals from first and second microphones, respectively; producing a differential electronic sound signal based on the first and second sound signals when an estimated noise level is greater than a first threshold; and alternatively producing a non-differential sound signal based on the first and second sound signals when the estimated noise level is less than greater than a second threshold.

As a method for dynamically controlling directional processing in the multi-microphone sound processing system, one embodiment of the invention includes at least the acts of: receiving first and second electronic sound signals from first and second microphones, respectively; estimating a noise level picked up by at least one of the first and second microphones; and dynamically controlling the directional processing based on the estimated noise level.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIG.1 shows a typical direction processing system in a two-microphone hearing aid;

FIG. 2 is a block diagram of a two-microphone directional processing system according to one embodiment of the invention;

FIG. 3 is a block diagram of a minimum estimate unit according to one embodiment of the invention;

FIG. 4 is a block diagram of a minimum estimate unit according to another embodiment of the invention;

FIG. 5 is a block diagram of an automatic on/off control unit according to one embodiment of the invention;

FIG. 6 is a schematic diagram of an automatic on/off control unit according to one embodiment of the invention;

FIG. 7 is a graph illustrating a relationship between directional processing (indicated by directional scale) and an input level for the automatic on/off control unit illustrated in FIG. 5; and

FIG. 8 is a graph illustrating a relationship between directional processing (indicated by directional scale) and an input level for the automatic on/off control unit illustrated in FIG. 6.

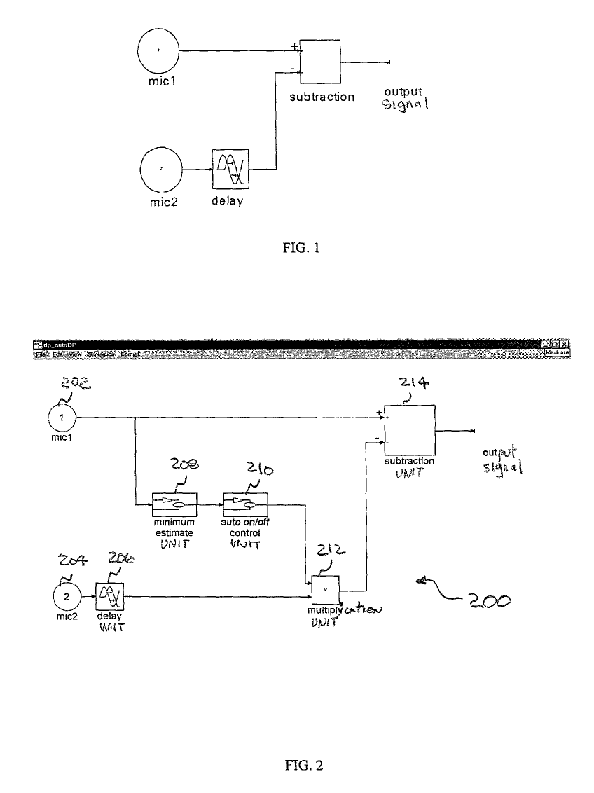

### DETAILED DESCRIPTION OF THE INVENTION

The invention relates to improved approaches to control directional processing in multi-microphone processing systems. These approaches operate to control activation/deactivation of directional processing in multi-microphone processing systems. As a result, directional processing can be automatically activated or deactivated based on the amount of interference (e.g., noise) in a listening environment. For instance, when the listening environment is noisy, directional processing is activated, and when the listening environment is quiet, directional processing is deactivated. These approaches are particularly useful for hearing aid applications in which directional noise suppression is important.

According to one aspect, the invention operates to measure noise level picked up by one or more of the microphones in a multi-microphone directional processing system, and then either activating the directional processing when the noise level is high or deactivating the directional processing when the noise level is low. Additionally, transitions between activation and deactivation of the directional processing can be made smoothly without annoying users.

Consequently, the invention enables multi-microphone directional processing systems to achieve automatic directional processing when needed The invention is described below with respect to embodiments particularly well suited for use with hearing aid applications. However, it should be recognized that the invention is not limited to hearing aid applications, but is applicable to other sound pick-up systems.

Embodiments of the invention are discussed below with reference to FIGS. 2-8. However, those skilled in the art will readily appreciate that the detailed description given herein with respect to these figures is for explanatory purposes as the invention extends beyond these limited embodiments.

FIG. 2 is a block diagram of a two-microphone directional processing system 200 according to one embodiment of the invention. The two-microphone directional processing system 200 includes a first microphone 202 and a second microphone 204. The first microphone 202 produces a first electronic sound signal and the second microphone 204 produces a second electronic sound signal. A delay unit 206 delays the second electronic sound signal. The two-microphone directional processing system 200 also includes a minimum estimate unit 208 and an automatic on/off control unit 210. The minimum estimate unit 208 estimates a minimum level for the first electronic sound signal. Typically, the minimum level is measured over a time constant duration, such that the minimum is a relatively long-term minimum. The automatic on/off control unit 210 produces a directional processing control signal that is sent to a multiplication unit 212. The multiplication unit 212 then multiplies the second electronic sound signal with the directional processing control signal at the multiplication unit 212 to produce a processed second electronic sound signal. The processed second electronic sound signal is thus processed to either perform directional processing or not perform directional processing. In one implementation, the multiplication unit 212 scales the second electronic sound signal by “1” when directional processing is to be performed, and scales the second electronic sound signal by “0” when directional processing is not to be performed. A subtraction unit 214 then subtracts the processed second electronic sound signal from the first electronic sound signal to produce an output signal. At this point, the output signal has undergone directional processing by the two-microphone directional processing system 200 when the noise level picked up by the first microphone 202 is sufficiently high. Such directional processing enables unwanted interference from certain directions to be suppressed. However, in cases where the noise level picked up by the first microphone 202 is low, the two-microphone directional processing system 200 does not perform directional processing. Consequently, the disadvantages of directional processing are automatically avoided when directional processing is not beneficial.

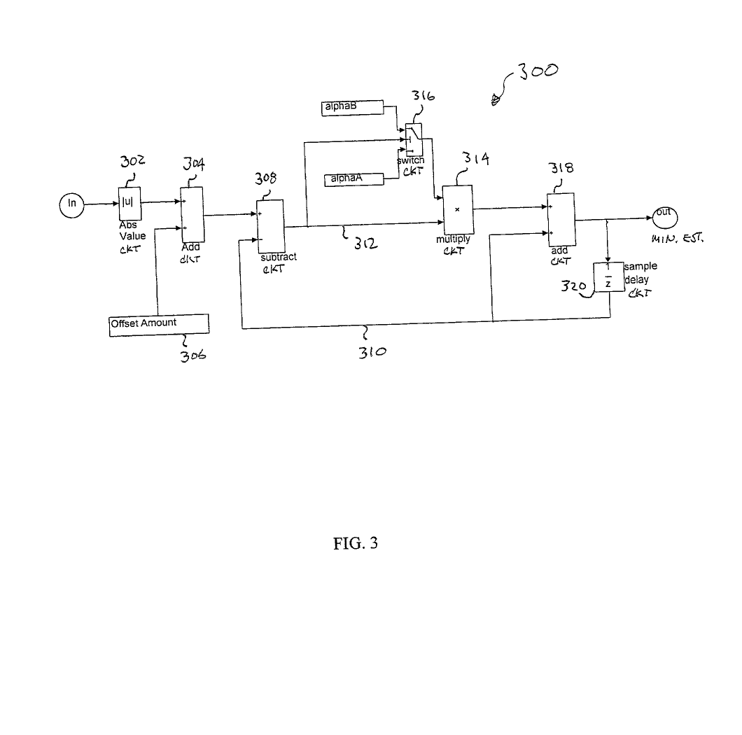

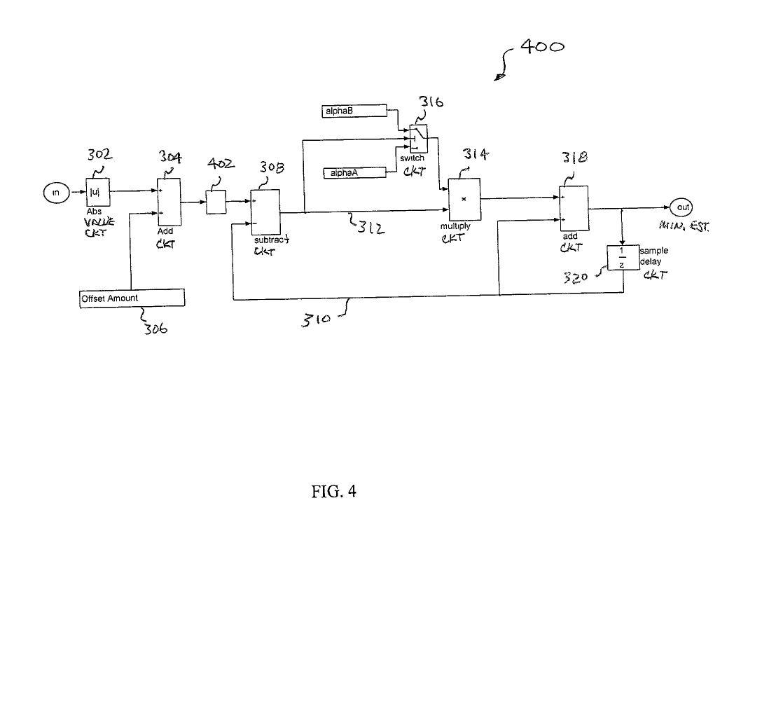

In this embodiment, minimum estimates and multiplication calculations are performed. The minimum estimates can, for example, be performed by minimum estimate units shown in more detail below with respect to FIGS. 3 and 4. It should also be noted that the delay unit 206 can be positioned within the two-microphone directional processing system 200 anywhere in the channel associated with the second electronic sound signal prior to the subtraction unit 214.

The minimum level being measured by the minimum estimate unit 208 represents an estimate of the noise level being packed-up by the first microphones. Although the two-microphone directional processing system 200 uses minimum estimates of the electronic sound signals produced by the first and second microphones 202 and 204, other signal characteristics can alternatively be used to measure noise level. For example, Root-Mean-Square (RMS) average of the electronic sound signals produced by the microphones could be used. With such an approach, the RMS average could be measured over a time constant duration. The time constant can be set such that the average is relatively long-term so as to avoid impact of signal fluctuations. The time constant with an RMS approach is likely to be longer than the time constant for the minimum approach.

FIG. 3 is a block diagram of a minimum estimate unit 300 according to one embodiment of the invention. The minimum estimate unit 300 is, for example, suitable for use as the minimum estimate unit discussed above with respect to FIG. 2. The minimum estimate unit 300 receives an input signal (e.g., electronic sound signal) that is to have its minimum estimated. The input signal is supplied to an absolute value circuit 302 that determines the absolute value of the input signal. An add circuit 304 adds the absolute value of the input signal together with an offset amount 306 and thus produces an offset absolute value signal. The addition of the offset amount, which is typically a small positive value, such as 0.000000000001, is used to avoid overflow in division or logarithm calculations performed in subsequent circuitry in the multi-microphone directional processing systems. The offset absolute value signal from the add circuit 304 is supplied to a subtract circuit 308. The subtract circuit 308 subtracts a previous output 310 from the offset absolute value signal to produce a difference signal 312. The difference signal 312 is supplied to a multiply circuit 314. In addition, the difference signal 312 is supplied to a switch circuit 316. The switch circuit 316 selects one of two constants that are supplied to the multiply circuit 314. A first of the constants, referred to as alphaB, is supplied to the multiply circuit 314 when the difference signal 312 is greater than or equal to zero. Alternatively, a second constant, referred to as alphaA, is supplied to the multiply circuit 314 when the difference signal 312 is not greater than or equal to zero. The constants, alphaA and alphaB, are typically small positive values, with alphaA being greater than alphaB. In one implementation, alphaA is 0.00005 and alphaB is 0.000005. The multiply circuit 314 multiplies the difference signal 312 by the selected constant to produce an adjustment amount. The adjustment amount is supplied to an add circuit 318. The add circuit 318 adds the adjustment amount to the previous output 310 to produce a minimum estimate for the input signal. A sample delay circuit 320 delays the minimum estimate by a delay (1/z) to yield the previous output 310 (where 1/z represents a delay operation).

FIG. 4 is a block diagram of a minimum estimate unit 400 according to another embodiment of the invention. The minimum estimate unit 400 is, for example, similar in design to the minimum estimate unit 300 illustrated in FIG. 3. The minimum estimate unit 400, however, further includes a linear-to-logarithm conversion unit 402 that converts the offset absolute value signal into a logarithmic offset signal before being supplied to the subtract circuit 308. The minimum estimate unit 400 is, for example, suitable for use as the minimum estimate unit discussed above with respect to FIG. 2. Optionally, a logarithm-to-linear conversion could be performed at the output of the minimum estimate circuit 400.

The two constants, alphaA and alphaB, are used in the minimum estimate units 300, 400 to determine how the minimum estimate changes with the input signal. Because the constant alphaA is greater than the constant alphaB, the minimum estimate tracks the valley level (or minimum level) of the input signal. Since the valley level is typically a good indicator of the noise level in the sound, the minimum estimate produced by the minimum estimate units 300, 400 is a good indicator of background noise level.

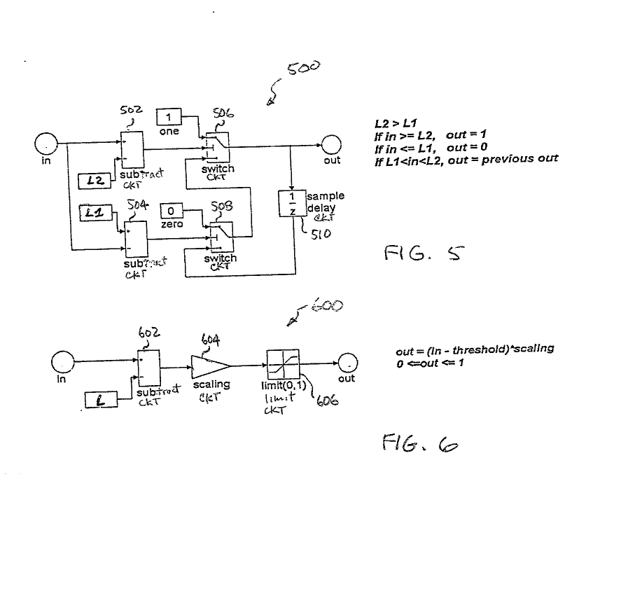

FIG. 5 is a block diagram of an automatic on/off control unit 500 according to one embodiment of the invention. The automatic on/off control unit 500 is, for example, suitable for use as the automatic on/off control unit 210 illustrated in FIG. 2. The automatic on/off control unit 500 includes a subtract circuit 502 and a subtract circuit 504. The subtract circuits 502 and 504 receive an input signal. The input signal, for example, represents the minimum estimate, such as the minimum estimate produced by the minimum estimate unit 208 illustrated in FIG. 2. The subtract circuit 502 also receives a second level setting (L2), and the subtract circuit 504 receives a first level setting (L1). The second level setting (L2) is greater than the first level setting (L1). The first level setting (L1) and the second level setting (L2) can be referred to as threshold amounts, levels or values. The subtract circuit 502 subtracts the second level setting (L2) from the input signal to produce a first control signal that is supplied to a switch circuit 506. The subtract circuit 504 subtracts the input signal from the first level setting (L1) to produce a second control signal that is supplied to switch circuit 508. Note that the input signals to the automatic on/off control unit 500 pertains to a noise level picked-up by one or more of the microphones. When the first control signal indicates that the input signal (i.e., noise level) is greater than the second level setting (L2), the switch circuit 506 causes a constant “1” value to be supplied as an output of the automatic on/off control unit 500. Alternatively, when the switch circuit 508 determines that the second control signal is less than the first level setting (L1), the switch circuit 508 outputs a “0” value which is passed through the switch circuit 506 and thus forms the output. The output of the automatic on/off control unit 500 is also coupled to a sample delay circuit 510 that subjects the output signal to a delay on the order of one sample. In other words, the sample delay circuit 510 delays the output signal by a delay (1/z) to yield a previous output (or delayed output) (where 1/z represents a delay operation). The previous output is fed back as another input to the switch unit 508. Hence, when the input signal to the automatic on/off control unit 500 is between the first level setting (L1) and the second level setting (L2), the output signal is held in its previous state. In other words, the delayed output produced by the sample delay circuit 510 is passed back through the switch circuit 508 and then through the switch circuit 506 to again become the output.

FIG. 6 is a schematic diagram of an automatic on/off control unit 600 according to one embodiment of the invention. The automatic on/off control unit 600 is, for example, also suitable for use as the automatic on/off control unit 210 illustrated in FIG. 2. The automatic on/off control unit 600 includes a subtract circuit 602. The subtract circuit 602 receives an input signal to the automatic on/off control unit 600. The input signal represents the noise level picked up by one of the microphones, such as one of the microphones 202 and 204 illustrated in FIG. 2. The subtract circuit also receives a reference level (L). The reference level (L) can be referred to as a threshold amount, level or value. The subtract circuit 602 subtracts the reference level (L) from the input signal to produce a value indicating the extent to which the input signal exceeds the reference level (L). This difference signal is then scaled by a scaling circuit 604. As an example, the scaling circuit can scale down the difference signal by 20% (0.05). The scaled difference signal produced by the scaling circuit 604 is then passed through a limit circuit 606 so that a resulting output signal has its amplitude limited to a value between 0 and 1.

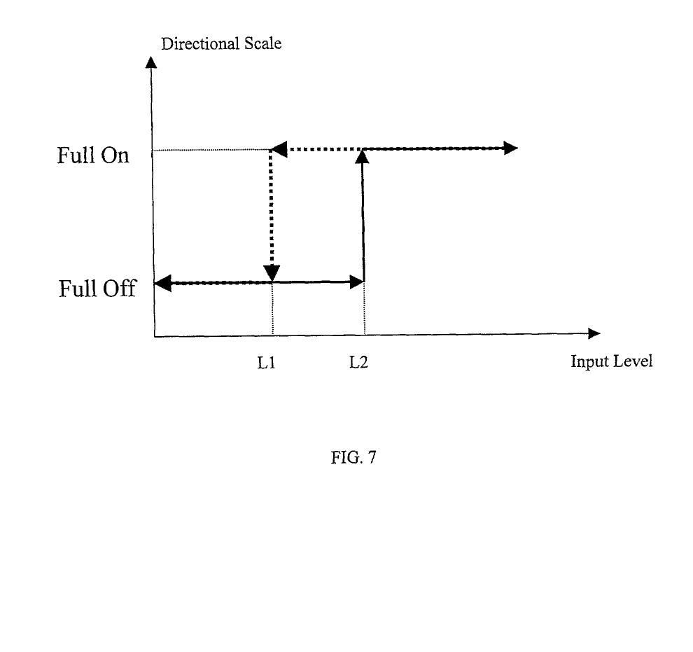

FIG. 7 is a graph illustrating a relationship between directional processing (indicated by directional scale) and an input level for the automatic on/off control unit 500 illustrated in FIG. 5. FIG. 7 indicates that a smooth transition between directional processing “on” and directional processing “off” is achieved. In effect, the transitioning between directional processing “on” and directional processing “off” enjoys a hysteresis characteristic to prevent rapid oscillations in switching directional processing “on” and “off”. More particularly, the first level setting (L1) is a constant that determines when to absolutely turnoff the directional processing, and the second level setting (L2) is a constant that determines when to absolutely turn-on the directional processing. When input signal (e.g., noise level) is less than the first level setting (L1), the directional scale is zero (“0”) and directional processing is turned off. When the input is greater than the second level setting (L2), the directional scale is one (“1”) and the directional processing is turned on. When the input is between the first level setting (L1) and the second level setting (L2), the directional scale does not change. That is, if the directional processing was “on” previously, it should stay “on”. If the directional processing was “off” previously, it should stay “off”. It is desirable to set the second level setting (L2) to be greater than the first level setting (Li). This is because the noise level usually does not vary much in a short time, thus setting the second level setting (L2) to be greater than the first level setting (LI) guarantees that the estimate variation of noise level by the “minimum estimate” will not frequently trigger the directional processing “on” and “off”. Therefore, a smooth transition between the two stages is achieved.

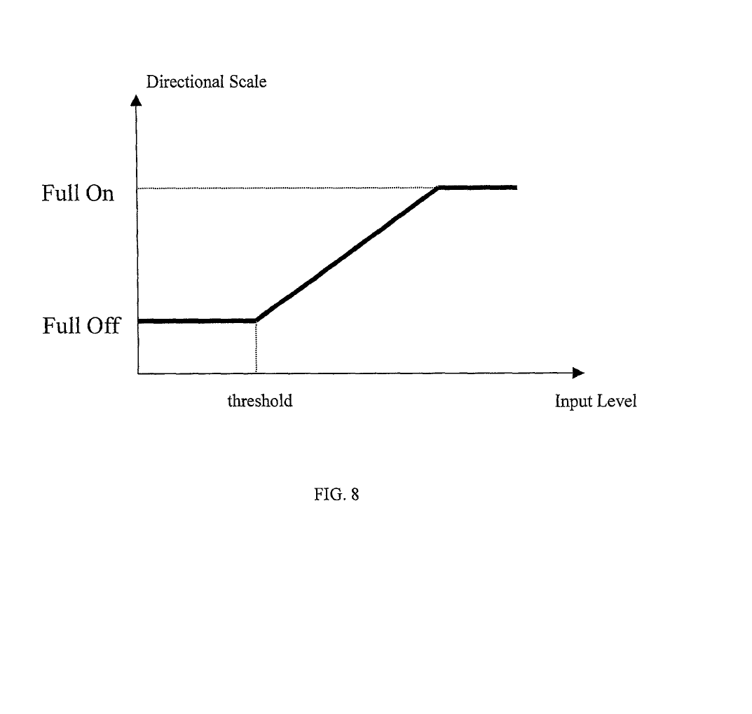

FIG. 8 is a graph illustrating a relationship between directional processing (indicated by directional scale) and an input level for the automatic on/off control unit 600 illustrated in FIG. 6. When the input level is less than the reference level (L) (threshold level), the directional processing is completely “off”. As the input level exceeds the threshold level, the directional processing is gradually performed more and more as the input level increases up to the condition in which the directional processing is completely “on”. More specifically, if the input signal (e.g., noise level) is less than the “threshold”, the directional scale is zero and the directional processing is turned “off”. If the input signal is greater than the “threshold”, the directional scale gradually increases as the input level goes up. The rate of the increase is determined by the scaling rate of the scaling circuit 604. If directional scale is one, the directional processing is fully “on”. If the directional scale is less than one but greater than zero, directional processing is on but less effective. Because the directional processing is gradually switched in as the noise level increases, the small variation in the noise estimate will not cause great change in the nature of the directional processing and therefore, the transition between directionality on and off is perceptually smooth.

The invention can also be combined with other inventions so as to share circuitry or otherwise complement one another. For example, the invention described herein can be combined with adaptive null processing techniques described in U.S. application Ser. No. 09/788,271, filed Feb. 16, 2001, and entitled “NULL ADAPTATION IN MULTI-MICROPHONE DIRECTIONAL SYSTEM”, the contents of which is hereby incorporated by reference, and/or the adaptive microphone sensitivity matching described in U.S. application Ser. No. 09/______, filed Mar. 14, 2001, and entitled “ADAPTIVE MICROPHONE MATCHING IN MULTI-MICROPHONE DIRECTIONAL SYSTEM”, the contents of which is hereby incorporated by reference.

The invention is preferably implemented in hardware, but can be implemented in software or a combination of hardware and software. The invention can also be embodied as computer readable code on a computer readable medium. The computer readable medium is any data storage device that can store data which can be thereafter be read by a computer system. Examples of the computer readable medium include read-only memory, random-access memory, CD-ROMs, magnetic tape, optical data storage devices, carrier waves. The computer readable medium can also be distributed over a network coupled computer systems so that the computer readable code is stored and executed in a distributed fashion.

The advantages of the invention are numerous. Different embodiments or implementations may yield one or more of the following advantages. One advantage of the invention is that directional processing to aid in interference suppression is automatically controlled. Another advantage of the invention is that directional processing is deactivated when not beneficial. Still another advantage of the invention is that directional processing is done in a manner that is perceptively smooth to the user.

The many features and advantages of the present invention are apparent from the written description and, thus, it is intended by the appended claims to cover all such features and advantages of the invention. Further, since numerous modifications and changes will readily occur to those skilled in the art, it is not desired to limit the invention to the exact construction and operation as illustrated and described. Hence, all suitable modifications and equivalents may be resorted to as falling within the scope of the invention.

What is claimed is:

1. A directional sound processing system, comprising:
at least first and second microphones spaced apart by a distance, said first microphone producing a first electronic sound signal and said second microphone producing a second electronic sound signal;
a noise level estimate circuit operatively coupled to said first or second microphone, said noise level estimate circuit operates to produce a noise level estimate associated with the first or second electronic sound signal from said first or second microphone; and
a directional processing circuit operatively connected to said first and second microphones and said noise level estimate circuit, said directional processing circuit operates to activated or deactivate directional processing with respect to the first and second electronic sound signals based on the noise level estimate.

2. A directional sound processing system as recited in claim 1, wherein when the noise level estimate is less than a threshold amount, said directional processing circuit deactivates the directional processing.

3. A directional sound processing system as recited in claim 1,
wherein when the noise level estimate is less than a first threshold amount, said directional processing circuit deactivates the directional processing, and
wherein when the noise level estimate is greater than a second threshold amount, said directional processing circuit activates the directional processing.

4. A directional sound processing system as recited in claim 3,
wherein the second threshold amount is greater than the first threshold amount, and
wherein when the noise level estimate is between the first threshold amount and the second threshold amount, said directional processing circuit does not change the activation or deactivation of the directional processing from its previous state.

5. A directional sound processing system as recited in claim 1, wherein said directional processing circuit comprises:
a directional processing control circuit operatively coupled to said noise level estimate circuit, said directional processing control circuit produces a control signal based on the noise level estimate and at least one threshold; and
a signal modification circuit operatively connected to said directional processing control circuit, said signal modification circuit operates to modify the second electronic sound signal in accordance with the control signal.

6. A directional sound processing system as recited in claim 5, wherein said directional processing circuit further comprises:
a combining circuit operatively connected to said signal modification circuit and said first microphone, said combining circuit operates to produce an output signal by combining the modified second electronic sound signal with the first electronic sound signal.

7. A directional sound processing system as recited in claim 6, wherein said directional sound processing system further comprises:
a delay circuit that delays the second electronic sound signal or the modified second electronic sound signal by a delay amount.

8. A directional sound processing system as recited in claim 6,
wherein the control signal is a scaling signal, and
wherein said signal modification circuit is a multiplication circuit that multiplies the second electronic sound signal with the control signal.

9. A directional sound processing system as recited in claim 6, wherein the control signal is one of a logical “1” and a logical “O”.

10. A directional sound processing system as recited in claim 6, wherein said combining circuit is a subtraction circuit.

11. A directional sound processing system as recited in claim 1, wherein said directional sound processing system further comprises:
a delay circuit that delays the second electronic sound signal by a delay amount.

12. A directional sound processing system as recited in claim 1, wherein said directional processing circuit comprises:
a directional processing control circuit operatively coupled to said noise level estimate circuit, said directional processing control circuit operates to produce a control signal based on the noise level estimate and at least one threshold; and
a scaling circuit operatively connected to said directional processing control circuit, said scaling circuit operates to scale the second electronic sound signal in accordance with the control signal; and
a subtraction circuit operatively connected to said scaling circuit and said first microphone, said subtraction circuit operates to produce an output difference signal by subtracting the scaled second electronic sound signal from the first electronic sound signal.

13. A directional sound processing system as recited in claim 12, wherein said directional sound processing system further comprises:
a delay circuit that delays the second electronic sound signal or the scaled second electronic sound signal by a delay amount.

14. A directional sound processing system as recited in claim 1, wherein said directional sound processing system resides within a hearing aid device.

15. A directional sound processing system, comprising:
at least first and second microphones spaced apart by a distance, said first microphone producing a first electronic sound signal and said second microphone producing a second electronic sound signal;
a minimum estimate circuit operatively coupled to said first or second microphone, said minimum estimate circuit produces a minimum estimate for the first or second electronic sound signal from said first or second microphone;
a directional processing control circuit operatively coupled to said minimum estimate circuit, said directional processing control circuit produces a control signal based on the minimum estimate; and
a scaling circuit operatively connected to said directional processing control circuit, said scaling circuit operates to scale the second electronic sound signal in accordance with the control signal; and
a subtraction circuit operatively connected to said scaling circuit and said first microphone, said subtraction circuit producing an output difference signal by subtracting the scaled second electronic sound signal from the first electronic sound signal.

16. A directional sound processing system as recited in claim 15, wherein said directional sound processing system further comprises:
a delay circuit that delays the second electronic sound signal or the scaled second electronic sound signal by a delay amount.

17. A directional sound processing system as recited in claim 15, wherein said scaling circuit comprises a multiplier.

18. A directional sound processing system as recited in claim 15, wherein said directional sound processing system resides within a hearing aid device.

19. In a hearing aid device having a multi-microphone sound processing device, a method for dynamically controlling directional processing in the multi-microphone sound processing system, said method comprising:
(a) receiving first and second electronic sound signals from first and second microphones, respectively;
(b) producing a differential electronic sound signal based on the first and second sound signals when an estimated noise level is greater than a first threshold; and
(c) alternatively producing a non-differential sound signal based on the first and second sound signals when the estimated noise level is less than greater than a second threshold.

20. A method as recited in claim 19, wherein the first threshold is greater than or equal to the second threshold.

21. A method as recited in claim 19, wherein the first and second microphones are provided within a hearing aid device, and wherein said method is performed by the hearing aid device.

22. A method for dynamically controlling directional processing in the multi-microphone sound processing system, said method comprising:
(a) receiving first and second electronic sound signals from first and second microphones, respectively;
(b) estimating a noise level picked up by at least one of the first and second microphones; and
(c) dynamically controlling the directional processing based on the estimated noise level.

23. A method as recited in claim 22, wherein said controlling (c) comprises:
(c1) comparing the estimated noise level to at least one threshold level to produce a directional processing control signal; and
(c2) controlling the directional processing in accordance with the directional processing control signal.

24. A method as recited in claim 23, wherein said controlling (c2) comprises scaling one of the first and second electronic sound signals processing in accordance with the directional processing control signal.

25. A method as recited in claim 22, wherein said controlling (c) comprises:
(c1) comparing the estimated noise level to a threshold level to produce a comparison signal; and
(c2) deactivating the directional processing when the estimated noise level is below the threshold level.

26. A method as recited in claim 22, wherein said controlling (c) comprises:
(c1) comparing the estimated noise level to a first threshold level to produce a first comparison signal;
(c2) comparing the estimated noise level to a second threshold level to produce a second comparison signal, the second threshold level being greater than the first threshold level;
(c3) deactivating the directional processing when the estimated noise level is below the first threshold level; and
(c4) activating the directional processing when the estimated noise level is greater than the second threshold level.

27. A method as recited in claim 26, wherein the second threshold level is greater than the first threshold level.

28. A method as recited in claim 22, wherein the first and second microphones are provided within a hearing aid device, and wherein said method is performed by the hearing aid device.

29. A method as recited in claim 22, wherein the noise level is estimate by a minimum estimator.
